(19) United States
(12) Patent Application Publication
(10) Pub. No.: US 2015/0179473 A1
(43) Pub. Date: Jun. 25, 2015

(54) DUAL WAVELENGTH ANNEALING METHOD AND APPARATUS

(71) Applicant: Applied Materials, Inc., Santa Clara, CA (US)

(72) Inventors: Aaron Muir HUNTER, Santa Cruz, CA (US); Joseph R. JOHNSON, Redwood City, CA (US)

(21) Appl. No.: 14/573,474

(22) Filed: Dec. 17, 2014

Related U.S. Application Data
(60) Provisional application No. 61/919,503, filed on Dec. 20, 2013.

(51) Int. Cl. H01L 21/324; H01L 21/263; H01L 21/268

(52) U.S. Cl. CPC H01L 21/324; H01L 21/2686; H01L 21/268; H01L 21/2636

(57) ABSTRACT

Methods and apparatus for thermal processing of semiconductor substrates are described. A solid state radiant emitter is used to provide a field of thermal processing energy. A second solid state radiant emitter is used to provide a field of activating energy. The thermal processing energy and the activating energy are directed to a treatment zone of the substrate, where the activating energy increases absorption of the thermal processing radiation in the substrate, resulting in thermal processing of the substrate in the areas illuminated by the activating energy.

### CROSS-REFERENCE TO RELATED APPLICATIONS

This application claims benefit of U.S. Provisional Patent Application Ser. No. 61/919,503, filed Dec. 20, 2013, which is incorporated herein by reference.

### FIELD

Embodiments described herein relate generally to the manufacture of semiconductor devices. More specifically, methods and apparatus described herein relate to thermal treatment methods and apparatus for forming crystalline semiconductors.

### DESCRIPTION OF THE RELATED ART

Thermal processing is a common practice in the semiconductor industry. Semiconductor substrates are exposed to thermal energy of particular intensity and/or type to accomplish a particular result, such as annealing or crystallization. Silicon, for example, is commonly annealed, crystallized, melted, and otherwise processed using heat energy and radiant energy of many different types.

Radiant energy sources are available in a broad range of wavelengths and spectra. However, the spectral power distribution of available radiant sources does not match the absorption spectrum of silicon. For example, lasers emitting at 1,064 nm are commonly used to anneal silicon substrates, but very high power must be used because silicon has poor absorption at 1,064 nm at room temperature. Similarly, silicon is substantially transparent to 980 nm radiation at room temperature. Absorption may improve at higher temperatures for some wavelengths, so some conventional processes involve heating the substrate to an intermediate temperature to boost absorption and then applying the radiation. Such methods have limited utility for smaller features because the background heating of the substrate causes diffusion of dopants and loss of concentration profile in very thin doped layers. Some have used longer wavelength radiation in the past, where silicon has stronger absorption, but long wavelength radiation, for example wavelengths of 8 μm to 16 μm is not useful for annealing the very thin (e.g. less than 100 nm thick) layers of leading edge and future node devices.

What is needed in the art is a method for using short wavelength radiation at moderate power delivery levels for thermal treatment of silicon and other semiconductor materials.

### SUMMARY OF THE INVENTION

Embodiments described herein provide methods and apparatus for treating a substrate using a moderate power source of treatment energy and a low power source of activating energy. In one aspect, a method of treating a substrate is described, including delivering a first energy exposure to a treatment area of the substrate at a wavelength between about 200 nm and about 850 nm and a power density between about 10 mW/cm² and about 10 W/cm², and delivering a second energy exposure to the treatment area of the substrate at a wavelength between about 800 nm and about 1,100 nm and a power level between about 50 kW/cm² and about 200 kW/cm².

In another aspect, a method of thermally processing a semiconductor substrate includes disposing the semiconductor substrate in a processing chamber; illuminating a first portion of the semiconductor substrate with a first radiant energy having a wavelength between about 200 nm and about 500 nm emitted by a non-amplifying medium at a power level between about 10 mW/cm² and about 10 W/cm²; illuminating a second portion of the semiconductor substrate surrounded by the first portion with a second radiant energy having a wavelength between about 800 nm and about 1,100 nm emitted by a laser source at a power level between about 50 kW/cm² and about 200 kW/cm²; and scanning the first radiant energy and the second radiant energy with respect to the substrate surface such that the second energy is surrounded by the first energy at all times during the scanning.

An apparatus for performing such methods includes a source of treatment energy having moderate power, such as between about 100 KW and 10 MW, a source of activating energy having low power, such as between about 1 W and about 100 W, and an optical system for directing the treatment energy and the activating energy to a treatment zone of the substrate to perform a thermal process.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method for thermally treating a semiconductor material according to one embodiment;

FIG. 2 is a perspective view of a thermal processing apparatus according to another embodiment.

FIG. 3 is a flow diagram summarizing a method according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

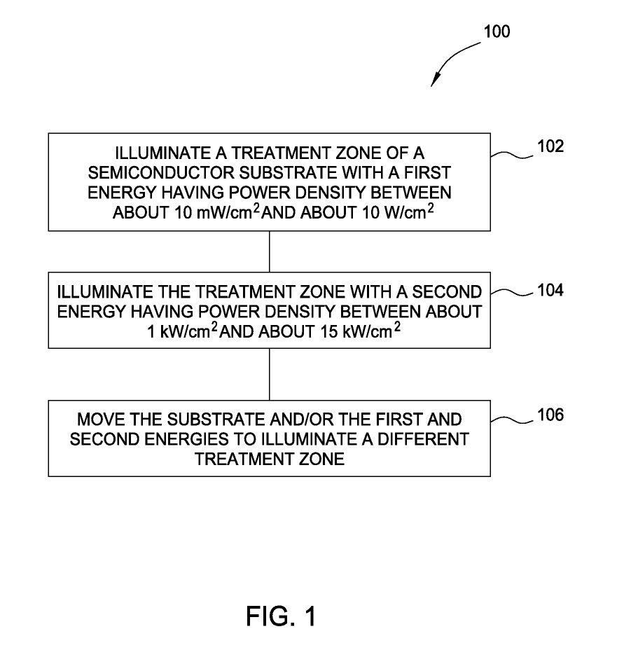

FIG. 1 is a flow diagram summarizing a method 100 for thermally processing a semiconductor substrate. In the method 100, a semiconductor substrate may be annealed, crystallized, or subjected to other thermal processes using radiant energy sources at power levels below about 10 kW. At 102, a portion of the substrate is illuminated with a first energy. The first energy is a radiant energy, may be a continuous wave or pulsed energy, and may have a wavelength between about 250 nm and about 800 nm. A near-UV wavelength such as between about 300 nm and about 500 nm, for example about 450 nm, may be used for the first energy. The first energy may have a power density between about 10 mW/cm² and about 10 W/cm², such as between about 50 mW/cm² and about 5 W/cm², for example about 1 W/cm². The first energy may be a surface activation energy that energizes electromagnetic energy carriers, such as electrons, holes, or phonons, on the substrate surface.

At 104, the portion of the substrate, which may be a treatment zone, is concurrently illuminated with a second energy. The second energy is a radiant energy, may be a continuous wave or pulsed energy, and may have a wavelength between about 800 nm and about 1,100 nm, such as between about 900 nm and about 1,100 nm, for example about 950 nm or about 1,064 nm. The second energy has a power density sufficient to cause a thermal transformation of the substrate surface. The second energy may be annealing energy, recrystallization energy, or melting energy. The power density of the second energy may be between about 20 kW/cm² and about 500 kW/cm², such as between about 50 kW/cm² and about 200 kW/cm², for example about 100 kW/cm².

Each of the first energy and the second energy may be correlated energy, such as energy from a laser, or uncorrelated energy, such as energy from a non-oscillating optical source, which may be a simple emitter, such as a non-amplifying emitter or medium, or an emitter coupled to an optical amplifier. Typically, the first energy will be emitted by a solid state source, such as a laser or light-emitting diode (LED), but a lamp emitter may also be used.

Each of the first energy and the second energy may be directed to the substrate using an optical system. Although not required, the optical system used for the first or the second energy may include components, such as homogenizers and/or diffusers, that increase the uniformity of the energy. The optical system may include refractive, reflective, transmissive, and absorbing components that steer the first energy along a desired optical path and shape the first energy into any desired shape. The first energy may, for example, be shaped into a line image, such as a thin rectangle, at the substrate surface. The optical system may also include components that reduce the uniformity of the first energy in a desired way. Graded refractive and/or diffusive components, such as GRIN components, may be used for such purposes.

The first energy and/or the second energy may be directed substantially perpendicular to the substrate surface, or at any angle between about the Brewster angle and perpendicularity, for example at an angle between about 45° and about 90°, such as between about 60° and about 90°, for example about 89° or any near-perpendicular angle, to a plane defined by the substrate surface. The first and second energies may be directed to the substrate surface at the same angle, or at different angles.

The first energy and the second energy may each be directed to the substrate surface to illuminate a portion of the treatment zone or the entire treatment zone. An image of the first energy on the substrate surface may be spaced apart from, adjacent to, overlapping with, or may surround an image of the second energy on the substrate surface. The image of the first energy may have the same shape as the image of the second energy or a different shape. For example, the image of the first energy may be round, oval, square, rectangular, line-shaped, or irregular in shape. Typically the image of the second energy will have a controlled shape to maintain control of the thermal transformation being caused in the substrate surface. In one embodiment, the second energy is shaped into a rectangle image of dimension about 100 μm by about 1 cm, and the first energy is shaped into a round spot image that surrounds the image of the first energy.

The first energy and the second energy may be patterned, if desired, to treat two or more portions concurrently. Diffractive components, such as diffraction gratings, Bragg gratings, beam splitters, and the like, may be used to divide the radiant field of the first energy and the second energy into two or more radiant fields that illuminate two or more different portions of the substrate surface. The system may be arranged such that the two or more different portions are adjacent, overlapping, or spaced apart. Dividing the first and second energies into two or more different radiant fields may also be useful for concurrent processing of two or more substrates. For example, a plurality of substrates may be positioned in registration with an optical system with an emitter of the first energy, an emitter of the second energy, a dividing system, and a steering system, such that a radiant field from the first energy emitter and the second energy emitter is delivered to a portion of each substrate concurrently.

At 106, the substrate and/or the first and second energies are moved so that a relative position of the substrate with respect to the first and second energies changes. The substrate may be positioned on a movable stage such as a precision x-y stage, x-y-z stage, r-θ stage, or the like. Alternately, or in addition, the energy sources and optical systems may be attached to a gantry that positions the radiation to illuminate the desired area of the substrate. The relative movement translates the treatment zone along the surface of the substrate such that all desired areas of the substrate surface are eventually treated. The treatment zone may be moved in a segmented linear pattern, such as a boustrophedonic pattern, or the treatment zone may be moved in a spiral pattern.

In an embodiment wherein the energy sources are continuous wave sources, the energy sources may be scanned across the substrate, or the substrate may be moved such that the radiation from the energy sources scans across the substrate surface. The scan rate is selected to provide a desired residence time of the treatment zone in the radiant field of the second energy source to accomplish the thermal process in the treatment zone. The scan rate may be between about 0.1 mm/sec and about 1 m/sec, such as between about 1 mm/sec and about 20 mm/sec, for example about 5 mm/sec. During the scanning, the relative positions of the images of the energy fields on the substrate surface may be maintained substantially constant, or the relative positions may change, if desired. In one embodiment, the first energy may be positioned differently with respect to the second energy when the treatment zone is near the edge of the substrate to compensate for edge effects.

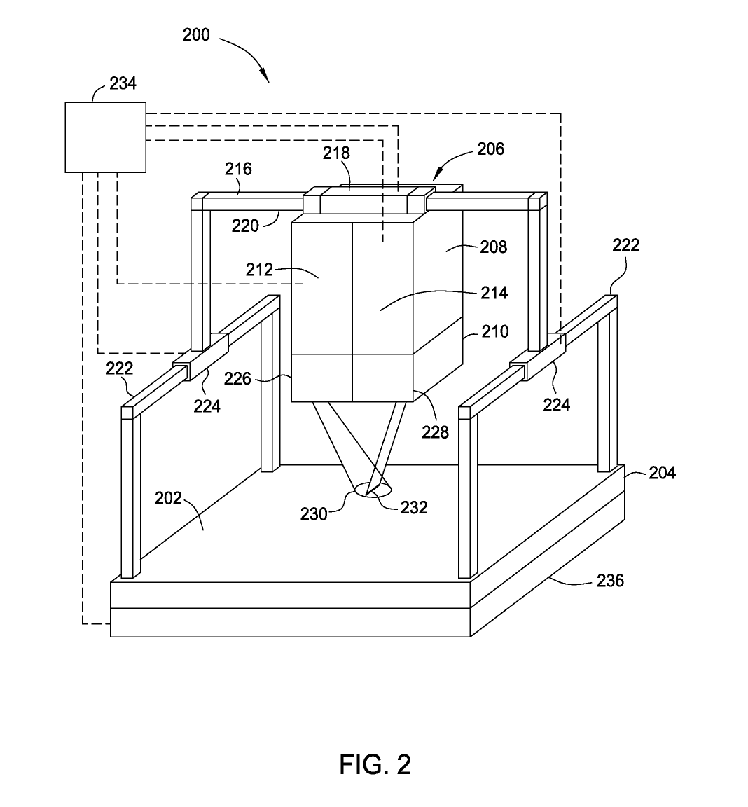

FIG. 2 is a schematic side view of an apparatus 200 according to one embodiment. The apparatus 200 may be used to perform embodiments of the method 100. The apparatus 200 is a thermal processing apparatus for performing thermal processes on semiconductor substrates. The apparatus 200 has a work surface 202 positioned on a stage 204 that is optionally movable. The stage 204 may be a precision x-y stage, x-y-z stage, x-θ stage, or the like. An energy assembly 206 is positioned to direct radiant energy toward the work surface 202. The energy assembly 206 has an energy source 208 and an optical assembly 210. The optical assembly 210 receives energy from the energy source 208 and transmits the energy to the work surface 202.

The energy source 208 has at least two energy emitters 212 and 214. The first energy emitter 212 may be a low power emitter, such as a lamp, an LED, a photodiode, or a low power laser such as a laser diode, and may emit radiation having a wavelength between about 250 nm and about 800 nm, such as between about 300 nm and about 500 nm, for example about 450 nm. The first energy emitter 212 may be a fiber coupled laser or a fiber coupled laser diode array. The first energy emitter 212 may emit radiant energy with a power between about 10 mW and about 10 W. The first energy emitter 212 may be a solid state emitter, such as a rare earth crystal or titanium sapphire laser, which may be frequency multiplied or tunable, or the first energy emitter 212 may be a semiconductor laser such as a GaN laser or an InGaN laser. The first energy emitter 212 may be a pulsed emitter, a continuous wave emitter, or a quasi-continuous wave emitter.

The second energy emitter 214 may be a moderate power emitter, emitting radiant energy at a power level between about 10 W and about 10 kW, such as between about 500 W and about 5 kW, for example about 1 kW. The second energy emitter 214 may be amplified. Typically, the second energy emitter 214 is a solid state device, such as a laser, a laser diode array, or an LED array with power output as described above. The second emitter 214 may emit radiant energy having a wavelength between about 800 nm and about 1,100 nm, such as between about 900 nm and about 1,100 nm, for example about 1,064 nm. The second emitter 214 may be a rare earth crystal laser, such as a Nd:YAG laser, or a titanium sapphire tunable laser. The second energy emitter 214 may be a pulsed emitter, a continuous wave emitter, or a quasi-continuous wave emitter.

The first and second energy emitters 212, 214 may be coupled to an optional gantry 216, which may be used to position the emitters 212, 214 at desired locations above the substrate surface. The gantry 216 may have a carriage 218 that is positionable on a rail 220 of the gantry 216. The gantry 216 typically has x-y positioning capability, so the rail 220 may ride on a pair of dual-rails 222, each of which has a carriage 224.

The optical assembly 210 may have refractive, reflective, diffractive, or absorptive components that direct radiant energy from the energy emitters 212, 214 to the work surface 202 such that the energy fields emitted by the emitters illuminate the work surface in a desired arrangement. The optical assembly 210 may have an isolated optical system for each energy emitter, or a combined optical system may direct radiant energy from more than one energy emitter to the work surface 202. The optical assembly 210 may shape, focus, and/or image the radiant energy from each of the energy emitters 212, 214 to have the same shape or different shapes. In one embodiment, the optical assembly 210 may have a first optical system 226 that shapes the radiant energy from the first energy emitter 212 into a field having a round or oval shape at the work surface 202 and a second optical system 228 that shapes the radiant energy from the second energy emitter 214 into a line image such as a rectangle of dimension 100 μm by 1 cm or 75 μm by 1.2 cm. The second optical system 228 may have an anamorphic component, such as a cylindrical lens or mirror, to help form the line image. Each of the optical systems 226, 228 has components such as lenses and mirrors that direct the energy fields from the two energy emitters 212, 214 to the work surface 202 in a relationship of close proximity, partial overlap, or complete overlap, as described above.

The optical elements in the optical systems 226, 228 may be movable, and may be actuated by rotational or linear actuators. For example, a steering optic may be included in the optical assembly 210 that may be rotated or moved linearly to steer any or all of the radiant energy fields to a desired location on the work surface 202. A controller 234 may be coupled to the carriages 218, 224 of the optional gantry 216, to an optional positioner 236 for the stage 204, to the energy sources 212, 214, and to the optical systems 226, 228, to control processes performed using the apparatus 200.

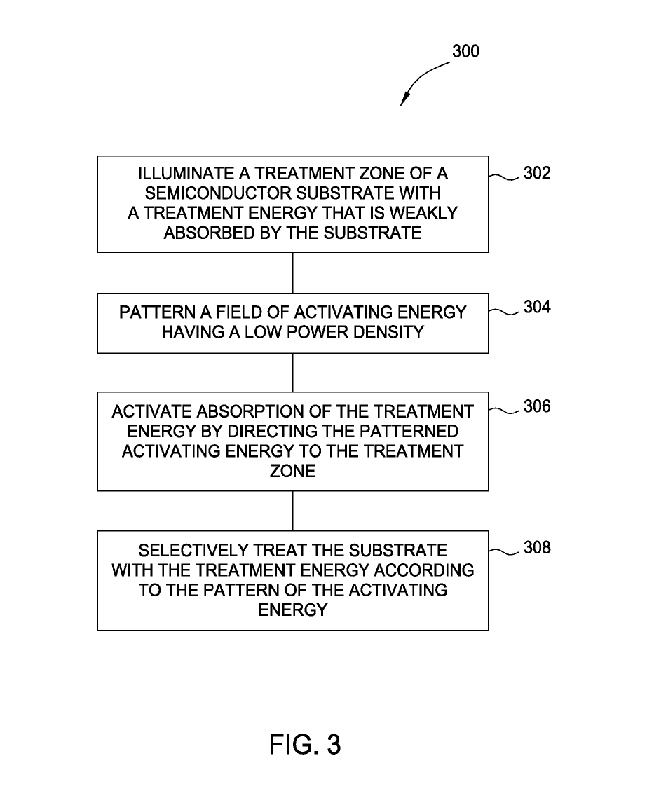

FIG. 3 is a flow diagram summarizing a method 300 according to another embodiment. The method 300 may be practiced using the other methods and apparatus described herein. Using the method 300, a selective thermal process may be performed on a semiconductor substrate according to a desired pattern.

At 302, a portion of a semiconductor substrate is exposed to a treatment energy that is, at best, only weakly absorbed by the substrate. The treatment energy has a power density sufficient to perform a thermal process on the portion of the substrate, except that the substrate has little or no absorption cross-section relative to the treatment energy, so that most of the treatment energy passes through the substrate unless measures are taken to alter the natural absorption cross-section of the substrate material. In one example, the substrate comprises or consists of silicon and the treatment energy is radiant energy having a wavelength of about 980 nm, at which silicon absorbs almost nothing. The treatment energy may have a power density between about 20 kW/cm² and about 500 kW/cm², such as between about 50 kW/cm² and about 200 kW/cm², for example about 100 kW/cm².

At 304, a field of activating energy having a low power density is patterned. The activating energy may be visible light having a wavelength between about 250 nm and about 800 nm, for example about 532 nm or about 700 nm. The activating energy may have a power level between about 0.1 W/cm² and about 10 W/cm², for example about 5 W/cm². The activating energy may be patterned using any convenient means, such as masking or diffracting. If a mask is used, the activating energy is typically imaged at a plane, and the mask is positioned on the image plane to afford a sharp, clear pattern to the activating energy. The mask may be a transmissive plate with a reflective material applied in a pattern that blocks the energy from passing through the plate, resulting in a patterned energy field.

At 306, absorption of the treatment energy by the substrate is activated by concurrently directing the patterned activating energy to the portion. The activating energy excites energy carriers in the surface of the substrate, as described above, increasing absorption of the treatment energy in the illuminated areas. If a sharp definition of the pattern is desired, the activating energy may be re-imaged on the surface of the substrate using appropriate optical components. Such components may be included in the optical system 226 of FIG. 2, for example.

At 308, the substrate is selectively treated using the treatment energy. The pattern of the activating energy defines the areas in which the treatment energy is absorbed by the substrate, resulting in a selective thermal process performed according to the pattern of the activating energy.

As with the method 100, the substrate surface is processed in parts, successive portions being processed by the radiation sequentially. For the method 300, the radiant energy may be continuous wave or pulsed energy. In one aspect, the treatment energy may be continuous wave energy while the activating energy is pulsed or quasi-continuous wave energy. For example, a first portion may be processed by providing a field of treatment energy at a portion of the substrate, switching on the patterned activating energy for a treatment duration, and then switching the patterned activating energy off. The substrate or the radiant energy sources may be moved to expose a second portion while maintaining the treatment energy, and when the second portion is appropriately positioned, the activating energy may be switched on to perform the thermal process on the second portion, and then switched off again. In this way, the entire substrate may be processed by moving the substrate and/or the energy sources and flashing or pulsing the activating energy, while maintaining the treatment energy in a continuous “on” state.

It should be noted that activation energy and treatment energy need not be illuminating a given area of a substrate concurrently. It is believed that the activation energy activates charge carriers at the substrate surface, which improves absorption of the treatment radiation by the substrate. Such charge carriers will remain activated for a short duration after illumination by activation energy ceases. While the charge carriers are active, the substrate will continue to absorb the treatment energy at an elevated level. Thus, the activation energy may be discontinued and, after a short duration, the treatment energy may be started. If the duration is less than the decay time of the active charge carriers, absorption of the treatment energy will still be elevated. The decay time of active charge carriers depends on the material and may be between about 0.1 μsec and about 1 msec, such as between about 1 μsec and about 500 μsec, for example about 200 μsec.

Thus, in one embodiment, an LED emitter of activation energy may illuminate a portion of the substrate. The LED emitter may be de-energized, and after a duration as described above, a laser emitter of treatment energy may be energized to deliver treatment energy to the portion. The activation energy and treatment energy may be any of the energy types described herein. Because the treatment energy is activated within the decay duration of the active charge carriers, absorption of the treatment energy remains elevated.

In some embodiments, a single energy source may be used. Energy sources capable of intense emissions of radiant energy at different wavelengths, such as tunable lasers, may be used to generate a first pulse of radiant energy at a first wavelength between about 250 nm and about 800 nm at a power level between about 10 mW/cm² and about 10 W/cm², such as between about 50 mW/cm² and about 5 W/cm², for example about 1 W/cm². The same energy emitter may then be used to generate a second pulse of radiant energy at a second wavelength between about 800 nm and about 1,100 nm at a power level between about 20 kW/cm² and about 500 kW/cm², such as between about 50 kW/cm² and about 200 kW/cm², for example about 100 kW/cm². The second pulse is generated after the first pulse, with an intervening duration that allows the lasing medium to be tuned to the second wavelength but that is not so long that the charge carriers activated by the first pulse deactivate. Typically, the duration between a 50% decay time of the first pulse and a 50% ramp-up time of the second pulse is from about 0.1 μsec to about 1 msec, such as about 1 μsec to about 500 μsec, for example about 200 μsec. As noted above, if scanning is used, the pulsing rate and scan rate are coordinated to treat all desired areas of a substrate.

While the foregoing is directed to embodiments of the present invention, other and further embodiments of the invention may be devised without departing from the basic scope thereof, and the scope thereof is determined by the claims that follow.

1. A method of treating a substrate, comprising:
delivering a first energy exposure to a portion of the substrate at a wavelength between about 200 nm and about 850 nm and a power density between about 10 mW/cm² and about 10 W/cm²; and
concurrently delivering a second energy exposure to the portion of the substrate at a wavelength between about 800 nm and about 1,100 nm and a power level between about 50 kW/cm² and about 200 kW/cm².

2. The method of claim 1, wherein the first energy and the second energy are produced by solid state light emitting devices.

3. The method of claim 1, wherein the first energy and the second energy are scanned across the substrate, and at least one of the first energy and the second energy is continuous wave energy.

4. The method of claim 1, wherein the first energy illuminates an area of the substrate larger than an area of the substrate illuminated by the second energy.

5. The method of claim 2, wherein the first energy is produced by a light emitting diode.

6. The method of claim 5, wherein the first energy has a wavelength between about 300 nm and about 500 nm.

7. The method of claim 6, wherein the second energy has a wavelength between about 900 nm and about 1,100 nm.

8. The method of claim 7, wherein the second energy is formed into a line shape at the substrate surface.

9. The method of claim 3, wherein the first and second energies are scanned across the substrate at a rate between about 5 cm/sec and about 100 cm/sec.

10. The method of claim 9, wherein the second energy is formed into a line shape at the substrate surface, and the first and second energies are scanned in a direction perpendicular to a major axis of the line shape.

11. The method of claim 10, wherein the first and second energies are scanned in a segmented linear pattern.

12. The method of claim 1, wherein the first energy is radiant energy having a near-UV wavelength.

13. The method of claim 12, wherein the first energy is emitted by a non-amplifying medium.

14. The method of claim 13, wherein the second energy is radiant energy having a near-IR wavelength.

15. The method of claim 14, wherein the second energy is emitted by one or more lasers.

16. A method of thermally processing a semiconductor substrate, comprising:
disposing the semiconductor substrate in a processing chamber;
illuminating a first portion of the semiconductor substrate with a first radiant energy having a wavelength between about 200 nm and about 500 nm emitted by a non-amplifying medium at a power level between about 10 mW/cm² and about 10 W/cm²;
concurrently illuminating a second portion of the semiconductor substrate surrounded by the first portion with a second radiant energy having a wavelength between about 800 nm and about 1,100 nm emitted by a laser source at a power level between about 20 kW/cm² and about 500 kW/cm²; and
scanning the first radiant energy and the second radiant energy with respect to the substrate surface such that the second energy is surrounded by the first energy at all times during the scanning.

17. The method of claim 16, wherein the first and second radiant energies are emitted by solid state emitters.

18. The method of claim 17, wherein the second radiant energy has a wavelength between about 900 nm and about 1,100 nm.

19. The method of claim 18, wherein at least one of the first and second radiant energies is continuous wave energy.

20. A method of performing a selective thermal process on a substrate, comprising:
exposing a portion of the substrate to a radiant energy field of radiation that is weakly absorbed by the substrate;
patterning an activating energy field by passing a second radiant energy field through a mask; and
directing the patterned activating energy field to the portion of the substrate.
